(19) United States
(12) Patent Application Publication
(10) Pub. No.: US 2025/0125829 A1
(43) Pub. Date: Apr. 17, 2025

(54) FULL-DUPLEX TRANSMISSION AND RECEPTION CIRCUIT, SERIAL CIRCUIT CHIP, ELECTRONIC DEVICE, AND VEHICLE

(71) Applicant: AI Micron Ltd., Shanghai (CN)

(72) Inventors: Yong Shen, Shanghai (CN); Xin Liu, Saratoga, CA (US); Wenbo Wang, Beijing (CN); Huayang Zeng, Shanghai (CN)

(21) Appl. No.: 18/948,131

(22) Filed: Nov. 14, 2024

(30) Foreign Application Priority Data
Oct. 13, 2023 (CN) 202311322740.2

(51) Int. Cl. H04B 1/40; H03F 3/19; H03K 17/687

(52) U.S. Cl. CPC H04B 1/40; H03F 3/19; H03K 17/6871

(57) ABSTRACT

A full-duplex transmission and reception circuit includes a transmission module, a filtering module, and an amplification module, with the transmission module having a current-mode logic architecture. A first terminal of the transmission module is connected to a first terminal of the filtering module, and a second terminal of the transmission module is connected to a second terminal of the filtering module. A third terminal of the filtering module is connected to both a first and a second terminals of the amplification module. The transmission module is configured to transmit a forward high-speed differential signal and receive a reverse low-speed common-mode signal. The filtering module is configured to filter out the forward high-speed differential signal from a mixed signal and transmit the reverse low-speed common-mode signals to the amplification module. The amplification module is configured to amplify the reverse low-speed common-mode signal.

### CROSS-REFERENCE TO RELATED APPLICATIONS

This application claims priority to Chinese Patent Application No. 202311322740.2, filed with the China National Intellectual Property Administration on Oct. 13, 2023, and entitled “Full-Duplex Transmission and Reception Circuit, Serial Circuit Chip, Electronic Device, and Vehicle,” which is incorporated herein by reference in its entirety.

### TECHNICAL FIELD

The present invention relates to the field of electronic and electrical technology, specifically to a full-duplex transmission and reception circuit, a serial circuit chip, an electronic device, and a vehicle.

### BACKGROUND

A Serializer-Deserializer (SERDES) system is a communication technology in which multiple low-speed parallel signals at the transmitting end are converted into high-speed serial signals. After transmission through media such as optical fibers or coaxial cables, the high-speed serial signals are converted back into low-speed parallel signals at the receiving end.

Currently, in related technologies, the connection between the serializer circuit and deserializer circuit is generally a unidirectional channel without a return path, as seen in HDMI (High Definition Multimedia Interface) and LVDS (Low Voltage Differential Signaling). Although some protocols, such as DP (DisplayPort), achieve return transmission of control information by adding additional channels, this approach increases costs, limiting its widespread application and posing certain limitations.

### SUMMARY

Based on this, it is necessary to address the above-mentioned defects or shortcomings by providing a full-duplex transmission and reception circuit, a serial circuit chip, an electronic device, and a vehicle, capable of achieving full-duplex communication over the same channel.

In the first aspect, the embodiments of the present invention provide a full-duplex transmission and reception circuit. The full-duplex transmission and reception circuit comprises a transmission module, a filtering module, and an amplification module, wherein the transmission module adopts a current-mode logic (CML) architecture.

A first terminal of the transmission module is connected to a first terminal of the filtering module, and a second terminal of the transmission module is connected to a second terminal of the filtering module. A third terminal of the filtering module is connected to both the first terminal and the second terminal of the amplification module.

The transmission module is configured to transmit forward high-speed differential signals and receive a reverse low-speed common-mode signal. The filtering module is configured to filter out the forward high-speed differential signal from a mixed signal and transmit the reverse low-speed common-mode signal to the amplification module. The amplification module is configured to amplify the reverse low-speed common-mode signal.

Optionally, in some embodiments of the present invention, the filtering module includes a first resistor and a second resistor.

A first terminal of the first resistor is connected to the first terminal of the transmission module, and a second terminal of the first resistor is connected to the first terminal of the amplification module. A first terminal of the second resistor is connected to the second terminal of the transmission module, and a second terminal of the second resistor is connected to both the second terminal of the first resistor and the second terminal of the amplification module.

Optionally, in some embodiments of the present invention, the amplification module includes an extraction unit and an amplification unit.

A first terminal of the extraction unit is connected to the third terminal of the filtering module, a second terminal of the extraction unit is grounded, and a third terminal of the extraction unit is connected to the first terminal of the amplification unit. A second terminal of the amplification unit is connected to the third terminal of the filtering module;

The extraction unit is configured to extract a DC level component of the reverse low-speed common-mode signal, and the amplification unit is configured to amplify the reverse low-speed common-mode signal based on the extracted DC level component.

Optionally, in some embodiments of the present invention, the extraction unit includes a third resistor and a capacitor.

A first terminal of the third resistor is connected to the third terminal of the filtering module, and a second terminal of the third resistor is connected to both a first terminal of the capacitor and a first terminal of the amplification unit. A second terminal of the capacitor is grounded.

Optionally, in some embodiments of the present invention, the amplification unit includes an analog front-end circuit.

Optionally, in some embodiments of the present invention, the transmission module includes a transmission unit and an output unit;

the first terminal of the transmission unit is configured to receive a first forward high-speed differential signal, and a second terminal of the transmission unit is connected to a first terminal of the output unit. A third terminal of the transmission unit is grounded, and a fourth terminal of the transmission unit is configured to receive a second forward high-speed differential signal. A fifth terminal of the transmission unit is connected to a second terminal of the output unit. A third terminal of the output unit is connected to a power supply, a fourth terminal of the output unit is connected to the first terminal of the filtering module, and the fifth terminal of the output unit is connected to the second terminal of the filtering module;

the transmission unit is configured to transmit the forward high-speed differential signal, and the output unit is configured to output the mixed signal to the filtering module.

Optionally, in some embodiments of the present invention, the transmission unit includes a first field-effect transistor (FET), a second field-effect transistor (FET), and a current source. A first terminal of the first FET is configured to receive the first forward high-speed differential signal, and a second terminal of the first FET is connected to the first terminal of the output unit. A third terminal of the first FET is connected to a first terminal of the current source, while a second terminal of the current source is grounded. A first terminal of the second FET is configured to receive the second forward high-speed differential signal, a second terminal of the second FET is connected to the second terminal of the output unit, and a third terminal of the second FET is connected to the first terminal of the current source;

the output unit includes a third FET, a fourth FET, a fourth resistor, and a fifth resistor. First terminals of both the third FET and the fourth FET are connected to a bias voltage. A second terminal of the third FET is connected to the second terminal of the transmission unit, and a third terminal of the third FET is connected to both a first terminal of the fourth resistor and the second terminal of the filtering module. A second terminal of the fourth FET is connected to the fifth terminal of the transmission unit, and a third terminal of the fourth FET is connected to both a first terminal of the fifth resistor and the first terminal of the filtering module. Second terminals of both the fourth resistor and the fifth resistor are connected to the power supply.

In a second aspect, the embodiments of the present invention provide a serial circuit chip, which includes any of the full-duplex transmission and reception circuits described in the first aspect.

In a third aspect, the embodiments of the present invention provide an electronic device, which includes a deserializer circuit chip, a transmission medium, and the serial circuit chip described in the second aspect. The transmission medium is arranged between the deserializer circuit chip and the serial circuit chip.

In a fourth aspect, the embodiments of the present invention provide a vehicle, which includes the electronic device described in the third aspect.

From the above technical solutions, it can be seen that the embodiments of the present invention have the following advantages:

the embodiments of the present invention provide a full-duplex transmission and reception circuit, a serial circuit chip, an electronic device, and a vehicle. The full-duplex transmission and reception circuit utilizes a transmission module based on a current-mode logic (CML) architecture to transmit forward high-speed differential signals and receive reverse low-speed common-mode signals. The filtering module filters out the forward high-speed differential signals from the mixed signal and transmits the reverse low-speed common-mode signals to the amplification module, which amplifies the reverse low-speed common-mode signals. This design enables full-duplex communication over the same channel, allowing the simultaneous transmission of forward high-speed differential signals and reception of reverse low-speed common-mode signals. Additionally, the use of common-mode signals helps reduce interference with the forward high-speed signals, facilitating long-distance transmission.

### BRIEF DESCRIPTION OF THE DRAWINGS

Other features, objectives, and advantages of the present invention will become more apparent from the following detailed description of non-limiting embodiments with reference to the accompanying drawings:

FIG. 1 is a structural block diagram of a full-duplex transmission and reception circuit provided by the embodiments of the present invention.

FIG. 2 is a specific example of the full-duplex transmission and reception circuit provided by the embodiments of the present invention.

FIG. 3 is a structural block diagram of a serial circuit chip provided by the embodiments of the present invention.

FIG. 4 is a structural block diagram of an electronic device provided by the embodiments of the present invention.

FIG. 5 is a structural block diagram of a vehicle provided by the embodiments of the present invention.

### REFERENCE NUMERALS

10—Full-duplex transmission and reception circuit, 101—Transmission module, 1011—Transmission unit, 1012—Output unit, 102—Filtering module, 103—Amplification module, 1031—Extraction unit, 1032—Amplification unit, 20—Serial circuit chip, 30—Electronic device, 301—Deserializer circuit chip, 302—Transmission medium, 40—Vehicle.

### DETAIL DESCRIPTION OF THE EMBODIMENTS

To enable those skilled in the art to better understand the solutions of the present invention, the technical solutions in the embodiments of the present invention will be clearly and thoroughly described below in conjunction with the accompanying drawings. It is evident that the described embodiments represent only a portion of the embodiments of the present invention, not all of them. All other embodiments obtained by those of ordinary skill in the art without inventive effort, based on the embodiments of the present invention, shall fall within the scope of protection of the present invention.

The terms “first,” “second,” “third,” “fourth,” etc., as used in the specification, claims, and the above drawings (if present), are intended to distinguish similar objects and are not necessarily used to indicate a specific sequence or order. It should be understood that such terms may be used interchangeably, where appropriate, so that the embodiments of the present invention can be implemented in sequences other than those illustrated or described herein.

Furthermore, the terms “comprise,” “include,” “have,” and any variations thereof are intended to cover non-exclusive inclusion. For example, a process, method, system, product, or device that comprises a series of steps or modules is not limited to the explicitly listed steps or modules but may include other steps or modules not explicitly listed or inherent to such process, method, product, or device.

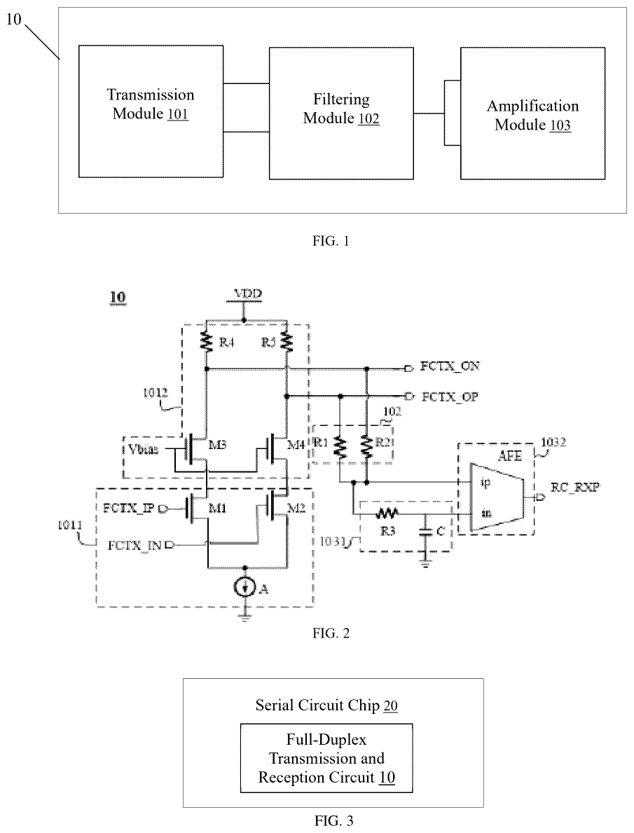

To facilitate a better understanding of the present invention, the following provides a detailed description of the full-duplex transmission and reception circuit, serial circuit chip, electronic device, and vehicle offered in the embodiments of the present invention, with reference to FIGS. 1 to 5.

Please refer to FIG. 1, which is a structural block diagram of a full-duplex transmission and reception circuit provided by the embodiments of the present invention. The full-duplex transmission and reception circuit 10 includes a transmission module 101, a filtering module 102, and an amplification module 103. The transmission module 101 adopts a Current Mode Logic (CML) architecture.

The first terminal of the transmission module 101 is connected to the first terminal of the filtering module 102, and the second terminal of the transmission module 101 is connected to the second terminal of the filtering module 102. The third terminal of the filtering module 102 is connected to both the first terminal and the second terminal of the amplification module 103. In practical use, the transmission module 101 in the embodiments of the present invention can transmit forward high-speed differential signals and receive reverse low-speed common-mode signals. The filtering module 102 is capable of filtering out the forward high-speed differential signals from the mixed signal and transmitting the reverse low-speed common-mode signals to the amplification module 103, which amplifies the reverse low-speed common-mode signals.

As an example, and as shown in FIG. 2, the specific circuit structure of each module within the full-duplex transmission and reception circuit 10 will be described in detail below. In the diagram, FC represents the forward channel, RC represents the reverse channel, TX denotes transmission, and RX denotes reception.

For example, in the embodiments of the present invention, the filtering module 102 includes, but is not limited to, a first resistor R1 and a second resistor R2. The first terminal of the first resistor R1 (corresponding to the first terminal of the filtering module 102) is connected to the first terminal of the transmission module 101. The second terminal of the first resistor R1 (corresponding to the third terminal of the filtering module 102) is connected to the first terminal of the amplification module 103. The first terminal of the second resistor R2 (corresponding to the second terminal of the filtering module 102) is connected to the second terminal of the transmission module 101. The second terminal of the second resistor R2 (corresponding to the third terminal of the filtering module 102) is connected to both the second terminal of the first resistor R1 and the second terminal of the amplification module 103.

For example, in the embodiments of the present invention, the filtering module 102 includes, but is not limited to, a first resistor (R1) and a second resistor (R2). The first terminal of the first resistor R1 (corresponding to the first terminal of the filtering module 102) is connected to the first terminal of the transmission module 101. The second terminal of the first resistor R1 (corresponding to the third terminal of the filtering module 102) is connected to the first terminal of the amplification module 103. The first terminal of the second resistor R2 (corresponding to the second terminal of the filtering module 102) is connected to the second terminal of the transmission module 101. The second terminal of the second resistor R2 (corresponding to the third terminal of the filtering module 102) is connected to both the second terminal of the first resistor R1 and the second terminal of the amplification module 103.

Furthermore, in the embodiments of the present invention, the extraction unit 1031 includes, but is not limited to, a third resistor (R3) and a capacitor (C). The first terminal of the third resistor R3 (corresponding to the first terminal of the extraction unit 1031) is connected to the third terminal of the filtering module 102. The second terminal of the third resistor R3 (corresponding to the third terminal of the extraction unit 1031) is connected to both the first terminal of the capacitor C and the first terminal of the amplification unit 1032. The second terminal of the capacitor C (corresponding to the second terminal of the extraction unit 1031) is grounded. The amplification unit 1032 may include an Analog Front-End (AFE) circuit.

Similarly, in the embodiments of the present invention, the transmission module 101 may include a transmission unit 1011 and an output unit 1012. The first terminal of the transmission unit 1011 (corresponding to FCTX_IP) is configured to receive a first forward high-speed differential signal. The second terminal of the transmission unit 1011 is connected to the first terminal of the output unit 1012, and the third terminal of the transmission unit 1011 is grounded. The fourth terminal of the transmission unit 1011 (corresponding to FCTX_IN) is configured to receive a second forward high-speed differential signal, and the fifth terminal of the transmission unit 1011 is connected to the second terminal of the output unit 1012. The third terminal of the output unit 1012 is connected to the power supply (VDD). The fourth terminal of the output unit 1012 (corresponding to the first terminal of the transmission module 101) is connected to the first terminal of the filtering module 102, while the fifth terminal of the output unit 1012 (corresponding to the second terminal of the transmission module 101) is connected to the second terminal of the filtering module 102.

Furthermore, in the embodiments of the present invention, the transmission unit 1011 includes, but is not limited to, a first field-effect transistor (M1), a second field-effect transistor (M2), and a current source (A). The first terminal of the first FET M1 (corresponding to the first terminal of the transmission unit 1011) is configured to receive a forward high-speed differential signal. The second terminal of the first FET M1 (corresponding to the second terminal of the transmission unit 1011) is connected to the first terminal of the output unit 1012, and the third terminal of the first FET M1 is connected to the first terminal of the current source A. The second terminal of the current source A (corresponding to the third terminal of the transmission unit 1011) is grounded. The first terminal of the second FET M2 (corresponding to the fourth terminal of the transmission unit 1011) is configured to receive another forward high-speed differential signal, and the second terminal of the second FET M2 (corresponding to the fifth terminal of the transmission unit 1011) is connected to the second terminal of the output unit 1012. The third terminal of the second FET M2 is connected to the first terminal of the current source A. Optionally, both the first FET M1 and the second FET M2 are NMOS transistors. In this case, the first terminal of the first FET M1 corresponds to the gate (g) of the NMOS transistor, the second terminal corresponds to the drain (d), and the third terminal corresponds to the source(s). Similarly, the first terminal of the second FET M2 corresponds to the gate (g) of the NMOS transistor, the second terminal to the drain (d), and the third terminal to the source(s).

The output unit 1012 includes, but is not limited to, a third field-effect transistor (M3), a fourth field-effect transistor (M4), a fourth resistor (R4), and a fifth resistor (R5). The first terminals of both the third FET M3 and the fourth FET M4 are connected to a bias voltage (Vbias). The second terminal of the third FET M3 (corresponding to the first terminal of the output unit 1012) is connected to the second terminal of the transmission unit 1011. The third terminal of the third FET M3 (corresponding to the fifth terminal of the output unit 1012) is connected to both the first terminal of the fourth resistor R4 and the second terminal of the filtering module 102. The second terminal of the fourth FET M4 (corresponding to the second terminal of the output unit 1012) is connected to the fifth terminal of the transmission unit 1011. The third terminal of the fourth FET M4 (corresponding to the fourth terminal of the output unit 1012) is connected to both the first terminal of the fifth resistor R5 and the first terminal of the filtering module 102. The second terminals of both the fourth resistor R4 and the fifth resistor R5 (corresponding to the third terminal of the output unit 1012) are connected to the power supply (VDD). Optionally, both the third FET M3 and the fourth FET M4 are NMOS transistors. In this case, the first terminal of the third FET M3 corresponds to the gate (g) of the NMOS transistor, the second terminal corresponds to the source(s), and the third terminal corresponds to the drain (d). Similarly, the first terminal of the fourth FET M4 corresponds to the gate (g) of the NMOS transistor, the second terminal to the source(s), and the third terminal to the drain (d).

The operation process of the full-duplex transmission and reception circuit 10 provided by the embodiments of the present invention will now be explained with reference to FIG. 2. First, the forward high-speed differential signal is transmitted through the first FET (M1) and the second FET (M2). Next, after passing through the third FET (M3), the fourth FET (M4), the fourth resistor (R4), and the fifth resistor (R5), the signal is output to the chip terminals FCTX_OP and FCTX_ON. At the same time, these chip terminals also receive the reverse low-speed common-mode signal sent from the deserializer circuit chip. Then, the mixed signal at the chip terminals passes through the first resistor (R1) and the second resistor (R2), filtering out the forward high-speed differential signal and retaining the reverse low-speed common-mode signal. Furthermore, after the reverse low-speed common-mode signal's DC level component is extracted through the third resistor (R3) and the capacitor (C), the analog front-end (AFE) amplifies the reverse low-speed common-mode signal based on the extracted DC level component. Practical testing results demonstrate that, based on a 40 nm process, the chip not only achieves full-duplex communication in both forward and reverse directions but also supports long-distance transmission and reception.

In another aspect, the embodiments of the present invention provide a serial circuit chip. As shown in FIG. 3, the serial circuit chip 20 includes, but is not limited to, the full-duplex transmission and reception circuit 10 corresponding to the embodiments illustrated in FIGS. 1 and 2.

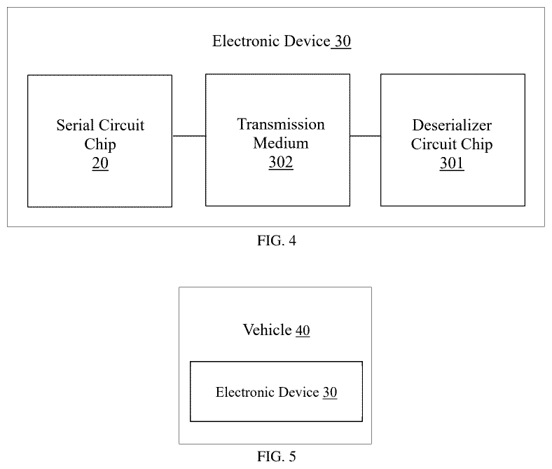

In another aspect, the embodiments of the present invention provide an electronic device. As shown in FIG. 4, the electronic device 30 may include a deserializer circuit chip 301, a transmission medium 302, and the serial circuit chip 20 corresponding to the embodiment in FIG. 3. The transmission medium 302 is arranged between the deserializer circuit chip 301 and the serial circuit chip 20. For example, the transmission medium 302 can be a shielded twisted pair (STP) or a coaxial cable (COAX).

In yet another aspect, the embodiments of the present invention provide a vehicle. As shown in FIG. 5, the vehicle 40 may include the electronic device 30 corresponding to the embodiment in FIG. 4.

The full-duplex transmission and reception circuit, serial circuit chip, electronic device, and vehicle provided by the embodiments of the present invention utilize the transmission module, based on a current-mode logic (CML) architecture, to transmit forward high-speed differential signals and receive reverse low-speed common-mode signals. The filtering module filters out the forward high-speed differential signals from the mixed signal and sends the reverse low-speed common-mode signals to the amplification module, which amplifies the reverse low-speed common-mode signals. This design allows simultaneous transmission of forward high-speed differential signals and reception of reverse low-speed common-mode signals over the same channel, achieving full-duplex communication. Furthermore, the use of common-mode signals reduces the adverse impact on the forward high-speed signals, facilitating long-distance transmission.

The technical features of the above embodiments can be combined in any way. For the sake of brevity, not all possible combinations of the technical features in the described embodiments are explicitly detailed. However, as long as there are no conflicts among the combinations of these technical features, they should be considered within the scope disclosed in this specification.

The above embodiments represent only a few implementations of the present invention. Although the descriptions are relatively specific and detailed, they should not be construed as limiting the scope of the invention. It should be noted that those skilled in the art may make various modifications and improvements without departing from the spirit of the invention, and all such variations fall within the scope of protection of the present invention.

What is claimed is:

1. A full-duplex transmission and reception circuit, comprising:
a transmission module, a filtering module, and an amplification module,
wherein:
a first terminal of the transmission module is connected to a first terminal of the filtering module, and a second terminal of the transmission module is connected to a second terminal of the filtering module; a third terminal of the filtering module is connected to both a first terminal and a second terminal of the amplification module; and
the transmission module is configured to transmit a forward high-speed differential signal and receive a reverse low-speed common-mode signal; the filtering module is configured to filter out the forward high-speed differential signal from a mixed signal and transmit the reverse low-speed common-mode signal to the amplification module; the amplification module is configured to amplify the reverse low-speed common-mode signal.

2. The full-duplex transmission and reception circuit according to claim 1, wherein:
the filtering module comprises a first resistor and a second resistor; a first terminal of the first resistor is connected to the first terminal of the transmission module, and a second terminal of the first resistor is connected to the first terminal of the amplification module; a first terminal of the second resistor is connected to the second terminal of the transmission module, and a second terminal of the second resistor is connected to both the second terminal of the first resistor and the second terminal of the amplification module.

3. The full-duplex transmission and reception circuit according to claim 1, wherein the transmission module has a current-mode logic architecture.

4. The full-duplex transmission and reception circuit according to claim 1, wherein:
the amplification module comprises an extraction unit and an amplification unit;
a first terminal of the extraction unit is connected to the third terminal of the filtering module, a second terminal of the extraction unit is grounded, and a third terminal of the extraction unit is connected to the first terminal of the amplification unit, while a second terminal of the amplification unit is connected to the third terminal of the filtering module;
the extraction unit is configured to extract a DC level component of the reverse low-speed common-mode signal, and the amplification unit is configured to amplify the reverse low-speed common-mode signal based on the extracted DC level component.

5. The full-duplex transmission and reception circuit according to claim 4, wherein:
the extraction unit comprises a third resistor and a capacitor;
a first terminal of the third resistor is connected to the third terminal of the filtering module, and a second terminal of the third resistor is connected to both a first terminal of the capacitor and a first terminal of the amplification unit;
a second terminal of the capacitor is grounded.

6. The full-duplex transmission and reception circuit according to claim 4, wherein the amplification unit comprises an analog front-end circuit.

7. The full-duplex transmission and reception circuit according to claim 1, wherein:
the transmission module comprises a transmission unit and an output unit;
a first terminal of the transmission unit is configured to receive a first forward high-speed differential signal, a second terminal of the transmission unit is connected to a first terminal of the output unit, and a third terminal of the transmission unit is grounded; a fourth terminal of the transmission unit is configured to receive a second forward high-speed differential signal, and a fifth terminal of the transmission unit is connected to a second terminal of the output unit; a third terminal of the output unit is connected to a power supply, a fourth terminal of the output unit is connected to the first terminal of the filtering module, and a fifth terminal of the output unit is connected to the second terminal of the filtering module;
the transmission unit is configured to transmit the forward high-speed differential signal, and the output unit is configured to output the mixed signal to the filtering module.

8. The full-duplex transmission and reception circuit according to claim 7, wherein:
the transmission unit comprises a first field-effect transistor (FET), a second field-effect transistor (FET), and a current source; a first terminal of the first FET is configured to receive the first forward high-speed differential signal, a second terminal of the first FET is connected to the first terminal of the output unit, and a third terminal of the first FET is connected to a first terminal of the current source; a second terminal of the current source is grounded; a first terminal of the second FET is configured to receive the second forward high-speed differential signal, a second terminal of the second FET is connected to the second terminal of the output unit, and a third terminal of the second FET is connected to the first terminal of the current source.

9. The full-duplex transmission and reception circuit according to claim 8, wherein:
the output unit comprises a third field-effect transistor (FET), a fourth field-effect transistor (FET), a fourth resistor, and a fifth resistor; a first terminal of the third FET and a first terminal of the fourth FET are both connected to a bias voltage; a second terminal of the third FET is connected to the second terminal of the transmission unit; a third terminal of the third FET is connected to a first terminal of the fourth resistor and to the second terminal of the filtering module; a second terminal of the fourth FET is connected to the fifth terminal of the transmission unit; a third terminal of the fourth FET is connected to a first terminal of the fifth resistor and to the first terminal of the filtering module; a second terminal of the fourth resistor and a second terminal of the fifth resistor are both connected to the power supply.

10. A serial circuit chip, comprising the full-duplex transmission and reception circuit according to claim 1.

11. An electronic device, comprising a deserializer circuit chip, a transmission medium, and the serial circuit chip according to claim 10, wherein the transmission medium is arranged between the deserializer circuit chip and the serial circuit chip.

12. A vehicle, comprising the electronic device according to claim 11.
